(19) United States
(12) Patent Application Publication
(10) Pub. No.: US 2009/0075707 A1
(43) Pub. Date: Mar. 19, 2009

(54) PORTABLE SLIDE TERMINAL OPENED IN A BAR SHAPE

(75) Inventor: Eun-Jung LEE, Seoul (KR)

Correspondence Address: THE FARRELL LAW FIRM, P.C., 333 EARLE OVINGTON BOULEVARD, SUITE 701, UNIONDALE, NY, 11553, US

(73) Assignee: Samsung Electronics Co., Ltd., Suwon-si (KR)

(21) Appl. No.: 12/210,649

(22) Filed: Sep. 15, 2008

(30) Foreign Application Priority Data
Sep. 17, 2007 (KR) 2007-0094115

(51) Int. Cl. H04M 1/02; H05K 7/00

(52) U.S. Cl. 455/575.4

(57) ABSTRACT

A portable terminal is provided, in which there is a first housing, a second housing is slidably engaged with the first housing, facing the first housing, and a connection member has one part slidably engaged with the first housing and another part slidably engaged with the second housing. The second housing slides to open or close a surface of the first housing with the guidance of the connection member and when the second housing is upright on a top end of the first housing, the second housing is selectively engaged with the first housing.

### PRIORITY

This application claims priority under 35 U.S.C. §119(a) to a Korean Patent Application filed in the Korean Intellectual Property Office on Sep. 17, 2007 and assigned Serial No. 2007-94115, the entire disclosure of which is hereby incorporated by reference.

### BACKGROUND OF THE INVENTION

1. Field of the Invention

The present invention generally relates to a portable terminal. More particularly, the present invention relates to a slide-type portable terminal having a pair of housings that are slidably engaged with each other, facing each others

2. Description of the Related Art

A portable terminal is a device that a user can carry with him, for the purpose of communications, information storage, multimedia contents, etc., such as a mobile phone, an electronic notebook, a Palm PC, or a portable gaining device. Among such portable terminals, mobile phones are the most popular. Owing to miniaturization and the development of integration technologies, the mobile phone is equipped with the functions of an electronic notebook, gaming, storing and reproduction of music/moving pictures, and capturing still images and moving pictures, as well as a communication function like a voice call.

According to their outward appearances, portable terminals are classified into a bar type with a single housing, a flip type with a flip cover added to the bar type, and a folder type with a pair of housings rotatably engaged with each other. Recently, a slide type with a pair of housings slidably engaged with each other and a swing type with a pair of housings rotatably engaged and facing each other have been on the market, thus meeting various users' demands.

In the portable terminal market where mobile phones are prevalent, the folder type and the slide type achieve high market shares, in which an input device and an output device are distributed to a pair of housings and the housings can be folded when carried and unfolded when used. The high market shares are attributed to the fact that slide-type or folder-type terminals facilitate miniaturization and are easy to use. Although the slide type was commercialized later than die folder type, the slide type has gained a greater market share than the folder type because it takes the advantages of the folder type and in addition, it is more convenient when opened and closed.

Along with the proliferation of portable terminals, users exhibit diverse tastes as to the outward designs of the portable terminals. For example, users purchase a separate case to protect their terminals and also decorate them. Some users paint their terminals according to their tastes.

However, the cost of decorating manufactured portable terminals imposes a constraint on users. In addition, conventional terminal designs have limitations in meeting users' ever-increasing demands.

### SUMMARY OF THE INVENTION

An aspect of exemplary embodiments of the present invention is to address at least the above problems and/or disadvantages and to provide at least the advantages described below. Accordingly, an aspect of exemplary embodiments of the present invention is to provide a portable terminal for satisfying users' different demands regarding the outward design of the portable terminal.

Another aspect of exemplary embodiments of the present invention provides a portable terminal for reducing the cost of decorating the appearance of the portable terminal by contributing to diversification of the outward designs of portable terminals.

A further aspect of exemplary embodiments of the present invention provides a portable terminal for used as a bar type in an office or a home and for use as a slide type when need.

In accordance with an aspect of exemplary embodiments of the present invention, there is provided a portable terminal in which there is a first housing; a second housing that is slidably engaged with the first housing, facing the first housing; and a connection member that has one part slidably engaged with the first housing and another part slidably engaged with the second housing. The second housing slides to open or close a surface of tie first housing with the guidance of the connection member and when the second housing is upright on top of the first housing, the second housing is selectively engaged with the first housing.

### BRIEF DESCRIPTION OF THE DRAWINGS

The above and other aspects, features and advantages of certain exemplary embodiments of the present invention will be more apparent from the following detailed description taken in conjunction with the accompanying drawings, in which:

FIG. 1 is a perspective view of a portable terminal according to an exemplary embodiment of the present invention;

FIG. 2 is an exploded perspective view of the portable terminal illustrated in FIG 1;

FIG. 3 illustrates the structure of a locker of the portable terminal illustrated in FIG. 1;

FIG. 4 is a lateral view of the portable terminal illustrated in FIG 1; and

FIG. 5 is a lateral view of the portable terminal illustrated in FIG. 1 in which a second housing is upright on top of a first housing so that they are vertically in a row.

Throughout the drawings, the same drawing reference numerals will be understood to refer to the same elements, features and structures.

### DETAILED DESCRIPTION OF EXEMPLARY EMBODIMENTS

The matters defined in the description such as a detailed construction and elements are provided to assist in a comprehensive understanding of exemplary embodiments of the invention. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

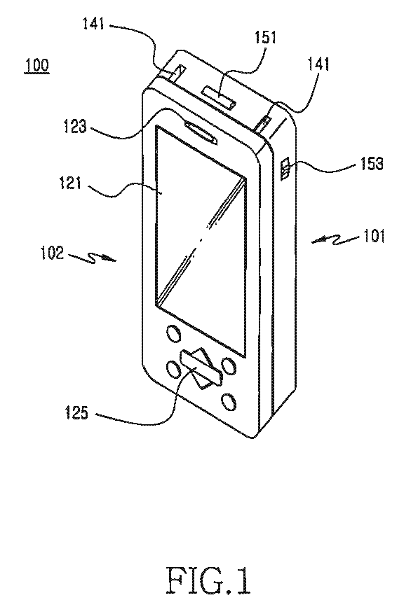

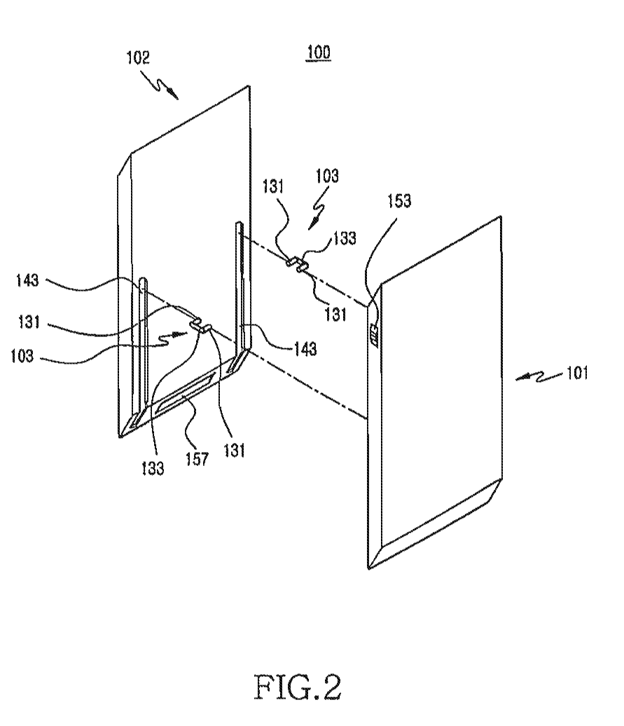

Referring to FIGS. 1 and 2, in a portable terminal 100 according to an exemplary embodiment of the present invention, first and second housings 101 and 102 are in slidable engagement, facing each other For the slidable engagement between the first and second housings 101 and 102, U-shaped connection members 103 are used.

Each of the connection members 103 has a connection portion 133 extended straight and sliding portions 131 extended straight in parallel from the connection portion 133, respectively. Although the connection members 103 are U-like shaped, their sliding portions 131 are bent at 90 degrees with respect to the connection portion 133, rather than curved. The shape of the connection members 103 may vary depending on a designer's intention in manufacture of an actual product.

The first housing 101 includes important circuits related to the operation of the portable terminal 100 such as a communication circuit, a storage circuit, etc. It also includes a battery pack (not shown) therein. Input devices (not shown) including a keypad and a transmitter are installed on a surface of the first housing 101, and the first housing 101 is opened and closed along with sliding of the second housing 102.

The second housing 102 is provided, on a surface thereof, with output devices including a display 121 and a receiver 123. Some function keys 125 can be disposed close to the display 121. Although the input devices are covered by the second housing 102, a user can still search stored information or read a received text message using the function keys 125.

One part of each of the connection members 103 is slidably engaged with the first housing 101 and another part of it is slidably engaged with the second housing 102. More specifically, each of the connection members 103 has a pair of sliding portions 131, one in slidable engagement with the first housing 101 and the other in slidable engagement with the second housing 102.

In the mean time, first guide grooves 141 and second guide grooves 143 are formed on the first housing 101 and the second housing 102, respectively, for providing paths to the connection members 103, specifically the sliding portions 131.

The first guide grooves 141 are elongated from a top end of the first housing 101 to one surface of the first housing 101, and the second guide grooves 143 are elongated from a bottom end of the second housing 102 to one surface of the second housing 102, which the one surface of the second housing 102 faces the one surface of the first housing 101 when the second housing 102 slides on the first housing 101. The guide grooves 141 and 143 are formed in pairs, close to both side end portions of the first and second housings 101 and 102. When the second housing 102 is mounted to the first housing 101, the first and second guide grooves 141 and 143 face each other at least partially, in alignment.

One of the sliding portions 131 in each of the connection members 103 is engaged with a first guide groove 141 and the other sliding portion 131 is engaged with a second guide groove 143 so that the connection member 103 guides the sliding movement of the second housing 102 while sliding along the guide grooves 141 and 143.

Meanwhile, the second housing 102 can slide over the first housing 101 with the guidance by the connection members 103 until the second housing 102 is on top end of the first housing 101 in a straight line on a same level. As the second housing 102 is upright on the top end of the first housing 101, the other surface of the second housing 102 and the one surface of the first housing 101 are substantially on the same plane. Thus, the user can use the portable terminal 100 like a bar type. To keep the second housing 102 upright on the top end of the first housing, the portable terminal 100 may be provided with a locker 105.

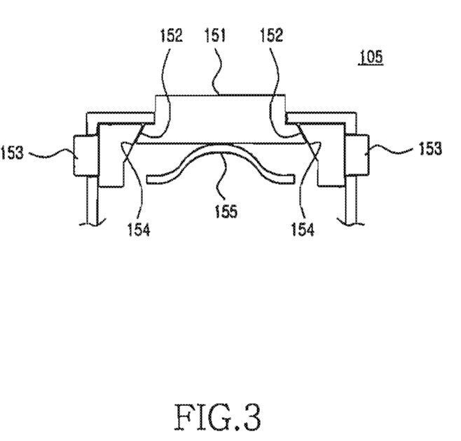

Referring to FIG. 3, the locker 105 is provided with a support protrusion 151 installed on the first housing 101, and a support hole 157 (in FIG. 2) on the second housing 102, for selectively being brought into engagement with the support protrusion 151.

The support protrusion 151 is extendable from and retractable into the first housing 101 and an elastic member 155 is installed within the first housing 101, for providing an elastic force to the support protrusion 151 so that the support protrusion 151 can extend outward from the first housing 101. The elastic member 155 is preferably a plate spring that can provide a sufficient elastic force even in a small space.

With the support protrusion 151 inserted into the support hole 157, the second housing 102 is stably kept, in an upright state, on the top end of the first housing 101 in a straight line. To slide the second housing 102 from this upright state, the support protrusion 151 should be removed from the support hole 157.

Release buttons 153 are formed on both side surfaces of the first housing 101. Inclined surfaces 154 and 152 are formed on the release buttons 153 and the support protrusion 15i respectively, facing each other in the first housing 101. When the user presses the release buttons 153, the support protrusion 151 enters the first housing 101 along the inclined surfaces 152 and 154. As a result, the locking state of the support protrusion 151 and the support hole 157 is released and thus the user can make a sliding movement of the second housing 102 again.

While the support protrusion 151 is disposed in the first housing 101 and the support hole 157 is formed in the second housing in the locker according to the exemplary embodiment of the present invention, it is to be clearly understood to those skilled in the art that the support protrusion 151 and the support hole 157 can be exchanged in position.

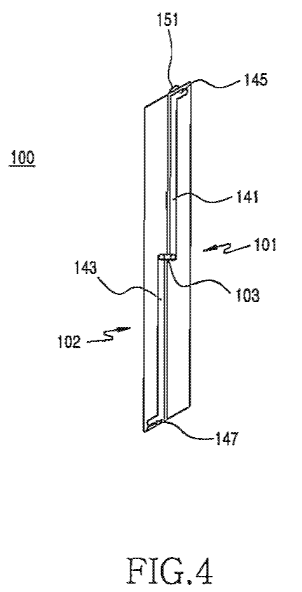

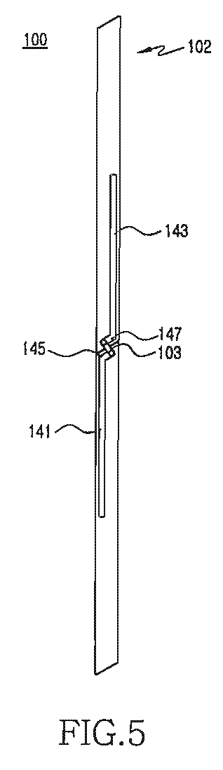

With reference to FIGS. 4 and 5, the sliding movement of the second housing 102 will be described in great detail.

FIG. 4 illustrates the positions of the first and second guide grooves 141 and 143 when the first and second housings 101 and 102 are overlapped. In this state, on the one surface of the first housing 101, the connection members 103 are in contact with the inner walls of first end portions of the first guide grooves 141 and with the inner walls of fist end portions of the second guide grooves 143. Therefore, the second housing 102 can move upward only, not downward in the overlapped state over the first housing 101.

As the second housing 102 slides upward from the overlapped position over the first housing 101, the connection members 103 move upward along the first guide grooves 141 on the first housing 101 and at the same time move downward along the second guide grooves 143 of the second housing 102. The second housing 102 can move upward until the connection members 103 move from the inner walls of the end portions of the first and second guide grooves 141 and 143 to bent portions 145 and 147 of the first and second guide grooves 141 and 143.

The first guide grooves 141 extend along the one surface of the first housing 101, inclinedly from the bent portion 145 and the second guide grooves 143 extend along the one surface of the second housing 102, inclinedly from the bent portion 147. Hence, when the connection members 103 move further upward from the position where they contact the bent portions 145 and 147 of the first and second guide grooves 141 and 143, they move along the inclinations of the first and second guide grooves 141 and 143 so that die second housing 102 stands upright on the top end of the first housing 101.

When the second housing 102 is uptight on the top end of the first housing 101, the other surface of the second housing 102 and the one surface of the first housing 101 are substantially on the same plane. At the same time, the connection members 103 are brought into contact with the inner walls of second end portions of the first and second guide grooves 141 and 143. Thus, the second housing 102 can move downward only, not further upward.

Meanwhile, with the second housing 102 upright on the top end of the first housing 101, the locker 105 inserts the support protrusion 151 into the support hole 157 to thereby keeping the second housing 102 stationary. That is, since the support protrusion 151 is kept protruding from tie top end of the first housing 101 and the support hole 157 is formed in the bottom end of the second housing 102, the support protrusion 151 is engaged into the support hole 157 as the second housing 102 slides to position upright on the top end of the first housing 101. Therefore, the portable terminal 100 can be used as a bar-type one in a home and an office.

To return the second housing 102 to the overlapped position over the first housing 101 from the upright position on the top end of the first housing 101, the user should release the locker 105 from the locking state by pressing the release buttons 153.

When the user presses the release buttons 153, the release buttons 153 press the support protrusion 151 inside the first housing 101. As the inclined surfaces 154 of the release buttons 153 interfere with the inclined surfaces 152 of the support protrusion 151, the support protrusion 151 retreats into the first housing 101. As a result, the support protrusion 151 is removed from the support hole 157 and thus the user can move the second housing 102 back to the overlapped position with respect to the first housing 101.

As is apparent from the above description, the portable terminal of the present invention can be changed between a slide type and a bar type. Therefore, the portable terminal can be used as a slide type, when a user carries it and can be used as a bar type in a home or an office. As two types of appearances can be represented with a single portable terminal, the present invention can meet diverse user demands and reduce the cost of decorating the looks of the portable terminal.

While the invention has been shown and described with reference to a certain exemplary embodiment of the present invention thereof, it is a mere exemplary application.

For example, while the sliding portions 131 of the connection members 103 are bent at 90 degrees from the connection portion 133 in the exemplary embodiment of the present invention, the connection portions 133 may be curved as stated before. Preferably, the connection members 103 are U-shaped.

Also, while the release buttons 153 are positioned on both side surfaces of the first housing 101 in installing the locker, they can be provided on another surface of the first housing 101. According to the changed positions of the release buttons 153, the positions of the inclined surfaces 152 and 154 of the support protrusion 151 and the release buttons 153 should be also changed.

Furthermore, the portable terminal is more convenient to carry than a conventional bar-type terminal and offers a wide space for sliding movement of housings. The resulting increased opened/closed area along with the sliding movement of the housings allows for as much additional installation of input devices, thereby contributing to diversification of functions in portable terminals.

While function keys are provided on a surface of the second housing 102 in the exemplary embodiment of the present invention, it can be further contemplated that the function keys 101 are positioned on the first housing 101 and the display is expanded to thereby reinforce a multimedia function.

In the exemplary embodiment of the present invention, the first guide grooves 141 extend from top to center on a surface of the first housing 101 and the second guide grooves 143 extend from bottom to center on a surface of the second housing 102. Yet, the first guide grooves 141 can be shortened and the second guide grooves 143 can be lengthened. One thing to note herein is that the connection members 103 should contact the inner walls of end portions of the first and second guide grooves 141 and 143 at the position where the second housing 102 fully overlaps the first housing 101.

Thus it will be understood by those skilled in the art that various changes in form and details may be made therein without departing from the spirit and scope of the present invention as defined by the appended claims and their equivalents.

What is claimed is:

1. A portable terminal comprising:
a first housing;
a second housing slidably engaged with the first housing while facing the first housing; and
a connection member having one part slidably engaged with the first housing and an other part slidably engaged with the second housing,
wherein the second housing slides to open, or to close one surface of the first housing with guidance of the connection member while one surface of the second housing facing the one surface of the first housing, and
the other surface of the second housing and the one surface of the first housing are substantially on a same plane in a position where the one surface of the first housing is fully opened.

2. The portable terminal of claim 1, wherein the connection member is U-shaped.

3. The portable terminal of claim 1, further comprising:
at least one first guide groove formed on the first housing; and
at least one second guide groove formed on the second housing, wherein the connection member is slidably engaged in the first and second guide grooves.

4. The portable terminal of claim 3, wherein the at least one first guide groove extends from a top end of the first housing to the one surface of the first housing, and the at least one second guide groove extends from a bottom end of the second housing to the one surface of the second housing.

5. The portable terminal of claim 3, wherein when the second housing overlaps over the first housing, the connection member contacts inner walls of first end portions of the first and second guide grooves, and when the second housing is upright on a top end of the first housing, the connection member contacts inner walls of second end portions of the first and second guide grooves.

6. The portable terminal of claim 3, wherein the at least one first guide groove is formed close to both side ends of the first housing and the at least one second guide groove is formed close to both side ends of the second housing.

7. The portable terminal of claim 1, further comprising:
a support protrusion protruding from one of a top end of the first housing and a bottom end of the second housing; and
a support hole formed in the other of the top end of the first housing and the bottom end of the second housing,
wherein when the second housing is upright on the top end of the first housing, the support protrusion is engaged in the support hole.

8. The portable terminal of claim 7, further comprising an elastic member installed adjacent to the support protrusion and providing an elastic force to protrude the support protrusion outward.

9. The portable terminal of claim 7, further comprising at least one release button in the first housing,
wherein when the at least one release button is pressed, the support protrusion retreats into the first housing.
